(19) United States
(12) Patent Application Publication
(10) Pub. No.: US 2023/0211375 A1
(43) Pub. Date: Jul. 6, 2023

(54) COATED SUBSTRATES FOR ELECTRONIC DEVICES

(71) Applicant: HEWLETT-PACKARD DEVELOPMENT COMPANY, L.P., SPRING, TX (US)

(72) Inventors: CHI HAO CHANG, TAIPEI CITY (TW); CHIEN-TING LIN, TAIPEI CITY (TW); KUAN-TING WU, TAIPEI CITY (TW)

(21) Appl. No.: 17/995,877

(22) PCT Filed: Apr. 15, 2020
(86) PCT No.: PCT/US2020/028203

§ 371 Date: Oct. 10, 2022

(51) Int. Cl. C23C 28/00; C23C 14/02; C23C 14/34; C23C 14/16; C23C 14/20; C23C 14/58; C25D 11/02; C25D 11/18

(52) U.S. Cl. CPC C23C 28/321; C23C 14/024; C23C 14/34; C23C 14/165; C23C 14/205; C23C 14/58; C25D 11/026; C25D 11/18

(57) ABSTRACT

A coated substrate for an electronic device can include a substrate, a physical vapor deposition layer over the substrate, and an anti-fingerprint layer over the physical vapor deposition layer. The physical vapor deposition layer can include an alloy of gold and platinum. The anti-fingerprint layer can include an ultraviolet radiation-cured polymer mixed with an anti-fingerprint material. The anti-fingerprint material can include a silane, a fluorinated polymer, a hydrophobic polymer, or a combination thereof.

### BACKGROUND

A variety of substrates can be used in electronic devices, for example as housings, cases, support structures, and so on. However, many substrate materials can be adversely affected in a natural environment, such as via corrosion, wear, etc. As such, these substrates are often coated to impart corrosion resistance, electrical resistance, wear resistance, decoration, and a variety of other desirable properties. Coatings can be applied via a variety of techniques. However, it can be difficult to achieve all desired characteristics for a coated substrate.

### BRIEF DESCRIPTION OF THE DRAWINGS

FIG. 1 is a cross-sectional view of an example coated substrate in accordance with examples of the present disclosure;

FIG. 2 is another cross-sectional view of an example coated substrate in accordance with examples of the present disclosure;

FIG. 3 is yet another cross-sectional view of an example coated substrate in accordance with examples of the present disclosure;

FIG. 4 is another cross-sectional view of an example coated substrate in accordance with examples of the present disclosure;

FIG. 5 is another cross-sectional view of an example coated substrate in accordance with examples of the present disclosure;

FIG. 6 is a flowchart illustrating an example method of making a coated substrate for an electronic device in accordance with examples of the present disclosure; and

FIG. 7 is a schematic view of an example electronic device in accordance with examples of the present disclosure.

### DETAILED DESCRIPTION

The present disclosure describes coated substrates for electronic devices, methods of making coated substrates for electronic devices, and electronic devices that include the coated substrates. The coated substrates can have high abrasion resistance, low friction, and anti-fingerprint properties. In one example, a coated substrate for an electronic device includes a substrate, a physical vapor deposition layer over the substrate, and an anti-fingerprint layer over the physical vapor deposition layer. The physical vapor deposition layer includes an alloy of gold and platinum. The anti-fingerprint layer includes an ultraviolet radiation-cured polymer mixed with an anti-fingerprint material. The anti-fingerprint material includes a silane, a fluorinated polymer, a hydrophobic polymer, or a combination thereof. In some examples, the substrate can include plastic, carbon fiber, or a light metal. In certain examples, the substrate can include aluminum, magnesium, lithium, titanium, or an alloy thereof, and the substrate can also have a micro-arc oxidation layer or a passivation layer on a surface of the substrate. In further examples, the physical vapor deposition layer can include from about 5 wt % to about 15 wt % gold and from about 85 wt % to about 95 wt % platinum. In other examples, the physical vapor deposition layer can have a thickness from about 30 nm to about 5 μm and the anti-fingerprint layer can have a thickness from about 10 nm to about 100 nm. In certain examples, the ultraviolet radiation-cured polymer of the anti-fingerprint layer can include a polyacrylic, a polyurethane, a urethane acrylate, an acrylic acrylate, an epoxy acrylate, or a combination thereof, and the anti-fingerprint material can include a fluorinated polyolefin, a fluoroacrylate, a fluorosilicone acrylate, a fluorourethane, a perflouropolyether, a perfluoropolyoxetane, a fluorotelomer, polytetrafluoroethylene, polyvinylidenefluoride, a fluorosiloxane, a fluorinated ultraviolet radiation-curable polymer, or a combination thereof. In further examples, the coated substrate can have a coefficient of friction from about 0.2 to about 0.3 when measured by rubbing against an aluminum ball, and a specific wear rate from about 10⁻⁹ mm³/Nm to about 10⁻⁸ mm³/Nm when measured by rubbing against an aluminum ball. In other examples, the coated substrate can also include a primer layer over the substrate and under the physical vapor deposition layer, wherein the primer layer includes a polymer. In still further examples, the coated substrate can also include a base coat layer over the primer layer, wherein the base coat layer includes a filler dispersed in a polymeric resin.

The present disclosure also describes methods of making coated substrates for electronic devices. In one example, a method of making a coated substrate for an electronic device includes depositing a physical vapor deposition layer over a substrate and depositing an anti-fingerprint layer over the physical vapor deposition layer. The physical vapor deposition layer includes an alloy of gold and platinum. The anti-fingerprint layer includes an ultraviolet radiation-cured polymer mixed with an anti-fingerprint material, wherein the anti-fingerprint material includes a silane, a fluorinated polymer, a hydrophobic polymer, or a combination thereof. In some examples, the substrate can include aluminum, magnesium, lithium, titanium, or an alloy thereof, and the method can also include forming a micro-arc oxidation layer or a passivation layer on a surface of the substrate. In other examples, the physical vapor deposition layer can be deposited by sputtering a gold and platinum alloy target that includes from about 5 wt % to about 15 wt % gold and from about 85 wt % to about 95 wt % platinum.

The present disclosure also describes electronic devices. In one example, an electronic device includes a housing carrying electronic components of the electronic device, and the housing includes a coated substrate. The coated substrate includes a substrate, a physical vapor deposition layer over the substrate, and an anti-fingerprint layer over the physical vapor deposition layer. The physical vapor deposition layer includes an alloy of gold and platinum. The anti-fingerprint layer includes an ultraviolet radiation-cured polymer mixed with an anti-fingerprint material, wherein the anti-fingerprint material includes a silane, a fluorinated polymer, a hydrophobic polymer, or a combination thereof. In certain examples, physical vapor deposition layer can include from about 5 wt % to about 15 wt % gold and from about 85 wt % to about 95 wt % platinum, and the ultraviolet radiation-cured polymer of the anti-fingerprint layer can include a polyacrylic, a polyurethane, a urethane acrylate, an acrylic acrylate, an epoxy acrylate, or a combination thereof, and the anti-fingerprint material can include a fluorinated polyolefin, a fluoroacrylate, a fluorosilicone acrylate, a fluorourethane, a perflouropolyether, a perfluoropolyoxetane, a fluorotelomer, polytetrafluoroethylene, polyvinylidenefluoride, a fluorosiloxane, a fluorinated ultraviolet radiation-curable polymer, or a combination thereof. In further examples, the electronic device can include a display, a personal computer, a laptop computer, a tablet, a media player, a smart device, a keyboard, or a combination thereof.

In addition to the examples described above, the coated substrates, methods of making coated substrates and the electronic devices will be described in greater detail below. It is also noted that when discussing the coated substrates, methods of making coated substrates, and electronic devices described herein, these relative discussions can be considered applicable to the other examples, whether or not they are explicitly discussed in the context of that example. Thus, for example, in discussing a physical vapor deposition layer related to a coated substrate, such disclosure is also relevant to and directly supported in the context of the methods of making coated substrates and electronic devices described herein, and vice versa.

### Coated Substrates for Electronic Devices

The coated substrates described herein can include certain coating layers that can give the substrates useful properties. In particular, the coated substrates can have high abrasion resistance and a low coefficient of friction. The coated substrates can also have anti-fingerprint properties. These properties can make the coated substrates useful as, for example, an exterior housing of an electronic device. In various examples, the coated substrates described herein can be used in electronic devices such as smartphones, tablet computers, laptop computers, televisions, and so on.

In certain examples, the coated substrates can include a combination of a physical vapor deposition (PVD) layer with an anti-fingerprint layer applied over the physical vapor deposition layer. The physical vapor deposition layer can include an alloy of gold and platinum. The anti-fingerprint layer can include an ultraviolet radiation-cured polymer mixed with an anti-fingerprint material. The anti-fingerprint material can include a silane, a fluorinated polymer, a hydrophobic polymer, or a combination thereof.

These coating layers can impart good abrasion resistance and friction properties to the substrate. In some examples, the coated substrate can have a coefficient of friction from about 0.2 to about 0.3 when measured by rubbing the coated substrate against an aluminum ball. This is significantly lower than the coefficient of friction for many materials. For example, aluminum metal has a coefficient of friction of about 1.1 when rubbed against an aluminum ball. The high abrasion resistance can be measured as a specific wear rate. In some examples, the coated substrates can have a low specific wear rate of about 10⁻⁹ mm³/Nm to about 10⁻⁸ mm³/Nm. In certain examples, the specific wear rate can be measured using a standard method according to ASTM G-99 standards. The specific wear rates approach the same specific wear rates of very hard materials such as diamonds and sapphires.

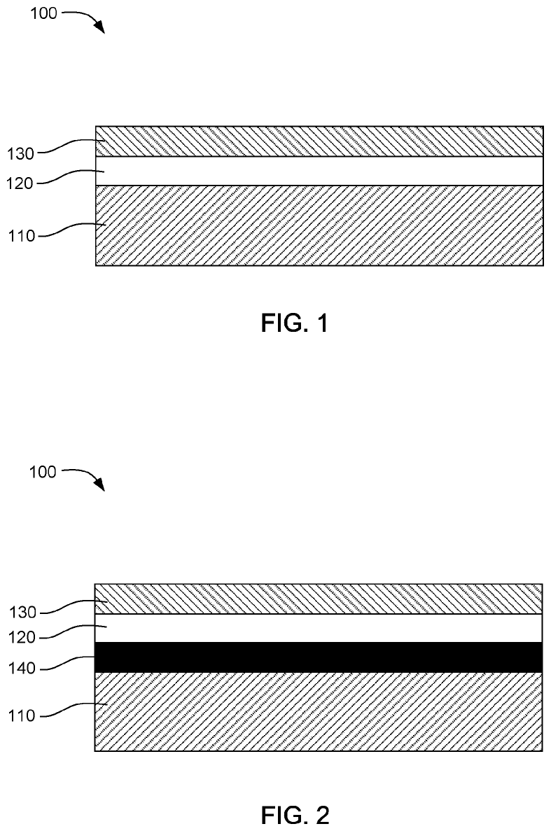

FIG. 1 shows a schematic view of one example coated substrate 100 in accordance with examples of the present disclosure. This example includes a substrate 110, a physical vapor deposition layer 120 deposited on the surface of the substrate, and an anti-fingerprint layer 130 deposited on the surface of the physical vapor deposition layer. In this example, the physical vapor deposition layer includes an alloy of gold and platinum. The anti-fingerprint layer includes an ultraviolet radiation-cured polymer mixed with an anti-fingerprint material. The anti-fingerprint material can include a silane, a fluorinated polymer, a hydrophobic polymer, or a combination thereof.

In further examples, the coated substrates described herein can include additional layers. In some examples, a coated substrate can include a primer layer. The primer layer can be deposited over the substrate. In certain examples, the primer layer can be deposited under the physical vapor deposition layer. The primer layer can include a polymer that can coat the surface of the substrate. FIG. 2 shows another example coated substrate 100 that includes a primer layer 140. This example includes a substrate 110. The primer layer is deposited onto the surface of the substrate in this example. A physical vapor deposition layer 120 is applied over the primer layer. An anti-fingerprint layer 130 is then applied over the top of the physical vapor deposition layer. As in the previous example, the physical vapor deposition layer can include an alloy of gold and platinum. The anti-fingerprint layer can include an ultraviolet radiation-cured polymer mixed with an anti-fingerprint material such as a silane, a fluorinated polymer, a hydrophobic polymer, or a combination thereof.

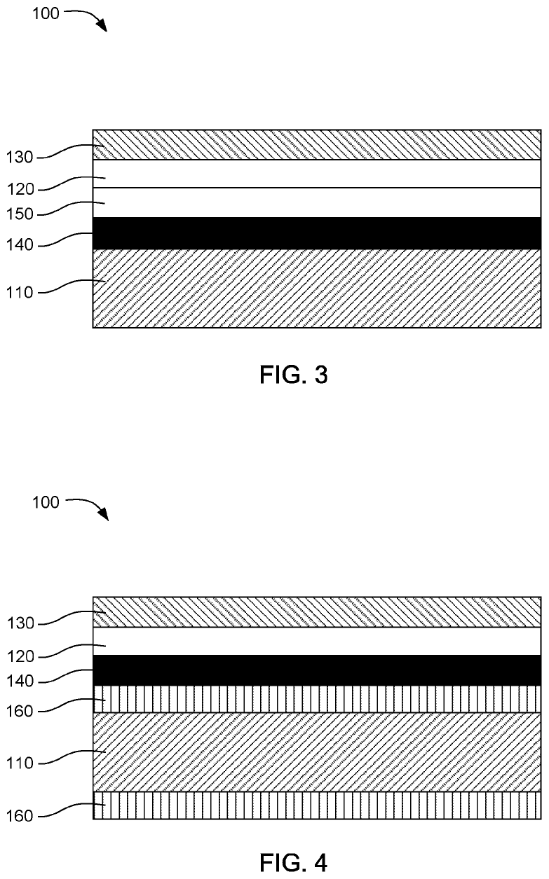

The coated substrate can also include a base coat layer in some examples. The base coat layer can be applied over a primer layer in some examples, although in other examples a base coat layer can be applied to a substrate without a primer layer. In some examples, the base coat layer can include a filler dispersed in a polymeric resin. The filler can include a particulate solid material. In some examples, the filler can be a pigment that can impart a specific color to the base coat layer. FIG. 3 shows another example coated substrate 100 that includes a substrate 110, a primer layer 140, and a base coat layer 150 applied over the primer layer. The primer layer can include a polymer, and the base coat layer can include a filler dispersed in a polymeric resin. This example also includes a physical vapor deposition layer 120 over the base coat layer and an anti-fingerprint layer 130 over the physical vapor deposition layer. The physical vapor deposition layer can include an alloy of gold and platinum. The anti-fingerprint layer can include an ultraviolet radiation-cured polymer mixed with an anti-fingerprint material such as a silane, a fluorinated polymer, a hydrophobic polymer, or a combination thereof.

In other examples, the substrate can be made of a metal such as a light metal. In certain examples, protective layers can be formed on one or both sides of the metal substrate. The protective layers can include a passivation layer or a micro-arc oxidation layer. Passivation layers can protect the metal substrate from corrosion or other chemical reactions in some examples. In some cases, passivation layers can be formed by treating the metal substrate with a passivation chemical such as a molybdate, vanadate, phosphate, chromate, stannate, manganese salt, or others. FIG. 4 shows an example coated substrate 100 that includes a substrate 110, such as a metal substrate. The substrate is treated with passivation chemicals to form a passivation layer 160 (or layers) on one or more typically, both sides of the substrate, e.g., metal substrate. A primer layer 140 is applied over the passivation layer. The primer layer can include a polymer as described above. A physical vapor deposition layer 120 is applied over the primer layer. The physical vapor deposition layer can include an alloy of gold and platinum. An anti-fingerprint layer 130 is applied over the physical vapor deposition layer. The anti-fingerprint layer can include a UV-cured polymer and an anti-fingerprint material as described above.

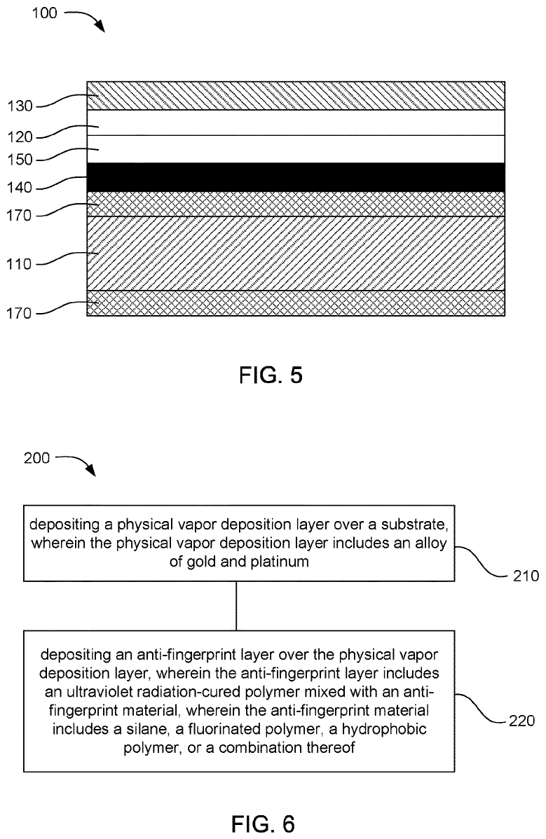

Micro-arc oxidation is another treatment that can be applied to certain metal substrates. In this process, a high voltage is applied to the metal substrate while in an electrolyte solution. The surface of the metal substrate becomes oxidized, forming a protective oxide layer. In some examples, a metal substrate can be treated with micro-arc oxidation before the coatings described herein are applied. FIG. 5 shows another example coated substrate 100 that includes a substrate 110, such as a metal substrate, with micro-arc oxidation layers 170 on both sides of the substrate. A primer layer 140 is applied to one side of the substrate over the micro-arc oxidation layer. A base coat layer 150 is applied over the primer layer. A physical vapor deposition layer 120 is applied over the base coat layer. An anti-fingerprint layer 130 is applied over the physical vapor deposition layer. The primer layer, base coat layer, physical vapor deposition layer, and anti-fingerprint layer can include the ingredients described above. The substrates and coating layers are described in more detail below.

### Methods of Making Coated Substrates for Electronic Devices

The present disclosure also describes methods of making coated substrates for electronic devices. These methods can include providing a substrate and applying coating layers to the substrate as described herein. In one example, a physical vapor deposition layer can be deposited on the substrate, followed by an anti-fingerprint layer. Other methods can include forming any of the other layers described above on the substrate.

FIG. 6 is a flowchart of a particular example method 200 of making a coated substrate for an electronic device. This method includes depositing a physical vapor deposition layer over a substrate, wherein the physical vapor deposition layer includes an alloy of gold and platinum 210, and depositing an anti-fingerprint layer over the physical vapor deposition layer, wherein the anti-fingerprint layer includes an ultraviolet radiation-cured polymer mixed with an anti-fingerprint material, wherein the anti-fingerprint material includes a silane, a fluorinated polymer, a hydrophobic polymer, or a combination thereof 220.

In some examples, the physical vapor deposition layer can be formed by sputtering. An alloy of gold and platinum can be used as a sputtering target. In certain examples, argon can be flowed as a sputtering gas during this process. Atoms of gold and platinum from the sputtering target can be deposited onto the substrate. The substrate can include other layers applied prior to sputtering, such as a primer layer and a base coat layer. In this case, the sputtered gold and platinum atoms can be deposited over the top of the layers already applied to the substrate. In certain examples, sputtering can be performed at a temperature from about 100° C. to about 180° C. and at a pressure from about 10⁻⁶ torr to about 10⁻⁴ torr. Sputtering can be continued until a desired layer thickness is achieved. In some examples, sputtering can be performed for a time from about 10 minutes to about 30 minutes.

The anti-fingerprint layer can include an ultraviolet radiation-cured polymer. This polymer can be in an uncured state prior to forming the anti-fingerprint layer. For example, an anti-fingerprint composition can include a UV-curable resin mixed with an anti-fingerprint material, such as a silane, a fluorinated polymer, a hydrophobic polymer, or a combination thereof. The composition can be applied to the surface of the coated substrate by a variety of application processes, such as spin coating, dipping, spraying, spreading, and so on. The composition can then be cured by exposure to UV radiation. In certain examples, the composition can be baked at a temperature from about 50° C. to about 60° C. for a period of time from about 10 minutes to about 15 minutes before exposure to UV radiation. After baking, the layer can be exposed to UV radiation at an intensity from about 700 mJ/cm² to about 1,200 mJ/cm² for about 10 seconds to about 30 seconds.

In further examples, methods can include forming additional coating layers on the substrate, such as passivation layers, micro-arc oxidation layers, primer layers, and base coat layers. In one example, a method of making a coated substrate can include forming a passivation layer on a light metal substrate. A physical vapor deposition layer can then be formed over the passivation layer. The physical vapor deposition layer can include an alloy of gold and platinum. An anti-fingerprint layer can be formed over the physical vapor deposition layer. The anti-fingerprint layer can include an ultraviolet radiation-cured polymer mixed with an anti-fingerprint material such as a silane, a fluorinated polymer, a hydrophobic polymer, or a combination thereof.

In a particular example, a passivation layer can be formed on a light metal substrate by immersing the substrate in a bath including a passivation chemical. Some examples of passivation chemicals can include molybdates, vanadates, phosphates, chromates, stannates, and manganese salts. The concentration of the passivation chemical in the bath can be from about 3 wt % to about 15 wt %. The passivation treatment can be performed for a time from about 20 seconds to about 120 seconds. The resulting passivation layer can have a thickness from about 1 μm to about 5 μm.

In another example, a method of making a coated substrate for an electronic device can include forming a micro-arc oxidation layer on a light metal substrate. A physical vapor deposition layer can then be formed over the micro-arc oxidation layer. The physical vapor deposition layer can include an alloy of gold and platinum. An anti-fingerprint layer can be formed over the physical vapor deposition layer. The anti-fingerprint layer can include an ultraviolet radiation-cured polymer mixed with an anti-fingerprint material such as a silane, a fluorinated polymer, a hydrophobic polymer, or a combination thereof.

In a particular example, a micro-arc oxidation layer can be formed by applying a voltage to a light metal substrate submerged in an electrolyte bath. In some examples, the voltage applied can be from about 150 V to about 550 V. Chemicals that can be included in the electrolyte bath can include sodium silicate, metal phosphate, potassium fluoride, potassium hydroxide, sodium hydroxide, fluorozirconate, sodium hexametaphosphate, sodium fluoride, ferric ammonium oxalate, phosphoric acid salts, graphite powder, silicon dioxide powder, aluminum oxide powder, metal powder, or combinations thereof. The chemicals can be mixed with water at a concentration of about 0.3 wt % to about 15 wt % of the chemical in water. In some examples, the pH of the electrolyte bath can be from about 9 to about 13. The light metal substrate can be immersed in the electrolyte bath and the voltage can be applied for a time period from about 2 minutes to about 25 minutes. The temperature of the electrolyte bath can be from about 10° C. to about 45° C. In further examples, the thickness of the micro-arc oxidation layer can be from about 2 μm to about 15 μm.

In yet another example, a method of making a coated substrate for an electronic device can include applying a primer layer to a substrate. The primer layer can include a polymer. In some examples, the substrate can be a light metal substrate with a passivation layer or micro-arc oxidation layer already formed. A physical vapor deposition layer can be formed over the primer layer. The physical vapor deposition layer can include an alloy of gold and platinum. An anti-fingerprint layer can be formed over the physical vapor deposition layer. The anti-fingerprint layer can include an ultraviolet radiation-cured polymer mixed with an anti-fingerprint material such as a silane, a fluorinated polymer, a hydrophobic polymer, or a combination thereof.

The primer layer can include a polymer, such as an epoxy, epoxy-polyester, polyester, or polyurethane. The polymer can be applied in a liquid form by a variety of application process, such as spin coating, dipping, spraying, spreading, and so on. After applying the polymer, the polymer can be cured by heating at a curing temperature for a period of time. In some examples, the curing temperature can be from about 60° C. to about 80° C. and the curing time can be from about 15 minutes to about 40 minutes. In further examples, the thickness of the primer layer can be from about 5 μm to about 20 μm.

In another example, a method of making a coated substrate for an electronic device can include applying a base coat layer to a substrate. In some examples, the substrate can have a passivation layer, micro-arc oxidation layer, or primer layer already applied. The base coat layer can include a filler dispersed in a polymeric resin. A physical vapor deposition layer can be applied over the base coat layer. The physical vapor deposition layer can include an alloy of gold and platinum. An anti-fingerprint layer can be formed over the physical vapor deposition layer. The anti-fingerprint layer can include an ultraviolet radiation-cured polymer mixed with an anti-fingerprint material such as a silane, a fluorinated polymer, a hydrophobic polymer, or a combination thereof.

The base coat layer can be applied by similar coating processes as the primer layer, such as spin coating, dipping, spraying, spreading, and so on. In some examples, the filler used in the base coat can be a solid particulate material such as carbon black, titanium dioxide, clay, mica, talc, barium sulfate, calcium carbonate, synthetic pigment, metallic powder, aluminum oxide, organic powder, inorganic powder, plastic beads, and color pigments. In certain examples, the base coat layer can also include a dye. The polymeric resin can be a liquid resin that can include monomers that polymerize to form a polymer, and/or already polymerized polymers that can cure to form a solid polymer layer. Some examples of polymers that can be included in the polymeric resin include polyester, polyacrylic, and polyurethane. The base coat layer can be applied at a thickness from about 10 μm to about 20 μm. After applying the filler and polymeric resin mixture, the layer can be cured. In some examples, the layer can be cured by heating to a temperature from about 60° C. to about 160° C. for a curing time of about 15 minutes to about 40 minutes.

### Electronic Devices

The coated substrates described herein can be used in a variety of electronic devices. For example, the substrates can be used as a housing, a cover, a frame, a support structure, the like, or a combination thereof for a variety of electronic devices. For example, the coated substrates can be used with a display, a personal computer, a laptop computer, a tablet, a media player, a smart device, a keyboard, the like, or a combination thereof.

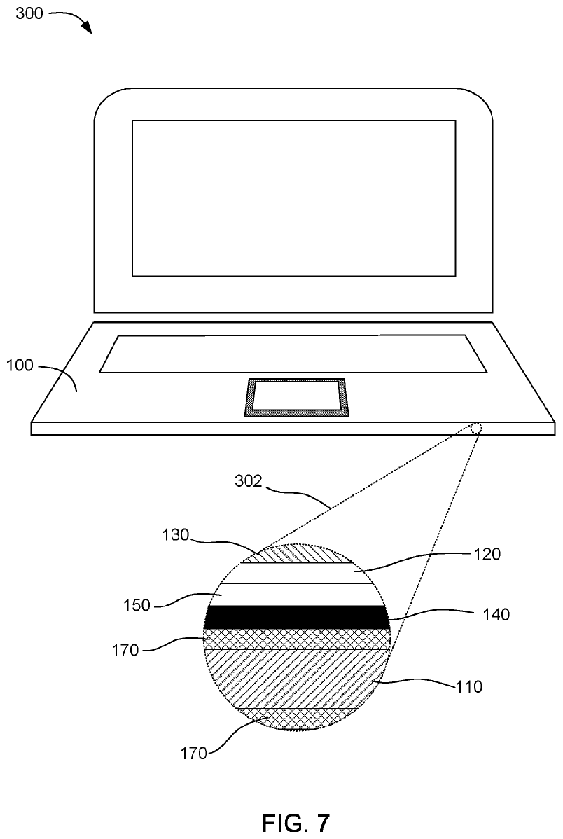

One non-limiting example of an electronic device in accordance with the present disclosure is presented in FIG. 7. In this example, the electronic device 300 is a laptop computer. A coated metal substrate 100 forms the housing of the laptop computer. A magnified cross-sectional view 302 of the coated metal substrate is also shown. The coated metal substrate includes a substrate 110, such as a metal substrate, with micro-arc oxidation layers 170 on both sides. A primer layer 140 and a base coat layer 150 are applied to the substrate. A physical vapor deposition layer 120 is applied over the base coat layer. An anti-fingerprint layer 130 is applied over the physical vapor deposition layer.

### Substrates

In some examples, the substrate can be a rigid material. Some examples of substrate materials can include plastic, carbon fiber, glass, composites, metals, and combinations thereof. In certain examples, the substrate can include a light metal such as aluminum, magnesium, titanium, lithium, niobium, or an alloy thereof. In some examples, alloys of these metals can include additional metals, such as bismuth, copper, cadmium, iron, thorium, strontium, zirconium, manganese, nickel, lead, silver, chromium, silicon, tin, gadolinium, yttrium, calcium, antimony, zinc, cerium, lanthanum, or others.

In further examples, the substrate can include carbon fiber. In particular, the substrate can be a carbon fiber composite. The carbon fiber composite can include carbon fibers in a plastic material such as a thermoset resin or a thermoplastic polymer. Non-limiting examples of the polymer can include epoxies, polyesters, polyacrylic, polycarbonate, vinyl esters, and polyamides.

In various examples, the substrate can be formed by molding, casting, machining, bending, working, or another process. In certain examples, the substrate can be a housing or chassis for an electronic device that is milled from a single block of metal or metal alloy. In other examples, an electronic device housing can be made from multiple panels.

The substrate is not particularly limited with respect to thickness. However, when used as a panel for an electronic device, such as for a housing or chassis, the thickness of the substrate chosen, the density of the material (for purposes of controlling weight, for example), the hardness of the material, the malleability of the material, the material aesthetic, etc., can be selected as appropriate for a specific type of electronic device, e.g., lightweight materials and thickness chosen for housings where lightweight properties may be commercially competitive, heavier more durable materials chosen for housings where more protection may be useful, etc. To provide some examples, the thickness of the substrate can be from about 0.5 mm to about 2 cm, from about 1 mm to about 1.5 cm, from about 1.5 mm to about 1.5 cm, from about 2 mm to about 1 cm, from about 3 mm to about 1 cm, from about 4 mm to about 1 cm, or from about 1 mm to about 5 mm, though thicknesses outside of these ranges can be used.

### Passivation Layers

In some examples, the substrate can be treated with a passivation treatment to form a passivation layer before other layers are coated onto the substrate. Passivation can be particularly useful for substrates made of light metals. In some cases, the passivation treatment can include immersing the substrate in a bath including a passivation chemical. Some examples of passivation chemicals can include molybdates, vanadates, phosphates, chromates, stannates, and manganese salts. In certain examples, the concentration of the passivation chemical in the bath can be from about 3 wt % to about 15 wt %. In other examples, the concentration can be from about 3 wt % to about 6 wt %, or from about 3 wt % to about 9 wt %, or from about 8 wt % to about 12 wt %, or from about 8 wt % to about 15 wt %. The remainder of the bath can be water. In further examples, the passivation treatment can be performed for a time from about 20 seconds to about 120 seconds. In other examples, the passivation treatment can be performed for a time from about 20 seconds to about 60 seconds, or from about 60 seconds to about 120 seconds, or from about 30 seconds to about 90 seconds. The resulting passivation layer can have a thickness from about 1 μm to about 5 μm in some examples. In other examples, the passivation layer thickness can be from about 1 μm to about 3 μm, or from about 3 μm to about 5 μm, or from about 2 μm to about 4 μm.

In other examples, the passivation chemicals can include a chelating agent. Non-limiting examples of chelating agents can include ethylenediaminetetraacetic acid (EDTA), ethylenediamine, nitrilotriacetic acid (NTA), diethylenetriaminepenta (methylenephosphonic acid) (DTPPH), nitrilotris(methylenephosphonic acid) (NTMP), 1-hydroxyethane-1,1-diphosphonic acid (HEDP), phosphoric acid, the like, or a combination thereof. In further examples, the passivation layer can include an organic acid in combination with aluminum, nickel, chromium, tin, indium, zinc, the like, or a combination thereof. Various combinations of the previously recited materials can also be employed.

### Micro-Arc Oxidation Layers

The substrate can be treated with a micro-arc oxidation treatment to form a micro-arc oxidation layer in some examples. This treatment is also particularly useful for light metal substrates. Micro-arc oxidation, also called plasma electrolytic oxidation, is an electrochemical process where the surface of a metal is oxidized using micro-discharges of compounds on the surface of the substrate when immersed in a chemical or electrolytic bath, for example. The electrolytic bath may include predominantly water with about 0.3 wt % to about 15 wt % electrolytic compound(s), e.g., alkali metal silicates, alkali metal hydroxide, alkali metal fluorides, alkali metal phosphates, alkali metal aluminates, the like, and combinations thereof. The electrolytic compounds may likewise be included at from about 1.5 wt % to about 3.5 wt %, or from about 2 wt % to about 3 wt %, though these ranges are not considered limiting. In one example, a high-voltage alternating current can be applied to the substrate to create plasma on the surface of the substrate. In this process, the substrate can act as one electrode immersed in the electrolyte solution, and the counter electrode can be any other electrode that is also in contact with the electrolyte. In some examples, the counter electrode can be an inert metal such as stainless steel. In certain examples, the bath holding the electrolyte solution can be conductive and the bath itself can be used as the counter electrode. A high direct current or alternating voltage can be applied to the substrate and the counter electrode. In some examples, the voltage can be 150 V or higher, such as about 150 V to about 550 V, about 250 V to about 550 V, about 250 V to about 500 V, or about 200 V to about 300 V. Temperatures can be from about 10° C. to about 45° C., or from about 25° C. to about 35° C., for example, though temperatures outside of these ranges can be used. This process can oxidize the surface to form an oxide layer from the substrate material. Various metal or metal alloy substrates can be used, including aluminium, titanium, lithium, magnesium, and/or alloys thereof, for example. The oxidation can extend below the surface to form thick layers, as thick as 30 μm or more. In some examples the oxide layer can have a thickness from about 2 μm to about 15 μm, from about 2 μm to about 12 μm, or from about 2 μm to about 10 μm, or from about 3 μm to about 10 μm, or from about 4 μm to about 7 μm. The oxide layer can, in some instances, enhance the mechanical, wear, thermal, dielectric, and corrosion properties of the substrate. The electrolyte solution can include a variety of electrolytes, such as a solution of potassium hydroxide. In certain examples, the electrolyte solution can include sodium silicate, metal phosphate, potassium fluoride, potassium hydroxide, sodium hydroxide, fluorozirconate, sodium hexametaphosphate, sodium fluoride, ferric ammonium oxalate, phosphoric acid salts, graphite powder, silicon dioxide powder, aluminum oxide powder, metal powder, or combinations thereof. In some examples, the substrate can include a micro-arc oxidation layer on one side, or on both sides.

### Primer Layers

A primer layer can be applied to the substrate in some examples. The primer layer can be formed by applying a liquid primer composition. The primer composition can be applied in a liquid form by a variety of application processes, such as spin coating, dipping, spraying, spreading, and so on. In some examples, the primer composition can include a thermally curable polymer resin. Examples of the polymer in the primer composition can include epoxy, epoxy-polyester, polyester, polyurethane, or others. After applying the polymer, the polymer can be cured by heating at a curing temperature for a period of time. In some examples, the curing temperature can be from about 60° C. to about 80° C. In further examples, the curing temperature can be from about 60° C. to about 70° C. or from about 70° C. to about 80° C. The primer layer can be heated at the curing temperature for a curing time. In some examples, the curing time can be from about 15 minutes to about 40 minutes, or from about 15 minutes to about 30 minutes, or from about 30 minutes to about 40 minutes. The thickness of the primer layer can be from about 5 μm to about 20 μm, or from about 5 μm to about 10 μm, or from about 10 μm to about 15 μm, or from about 15 μm to about 20 μm.

### Base Coating Layers

In some examples, a base coat layer can be applied over the substrate. In some examples, the base coat layer can be applied over a primer layer on the substrate. In other examples, the base coat layer can be applied directly to the substrate without a primer layer. The base coat layer can be applied by similar coating processes as the primer layer, such as spin coating, dipping, spraying, spreading, and so on.

The base coat layer can include a filler dispersed in a polymeric resin. In some examples, the filler used in the base coat can be a solid particulate material such as carbon black, titanium dioxide, clay, mica, talc, barium sulfate, calcium carbonate, synthetic pigment, metallic powder, aluminum oxide, organic powder, inorganic powder, plastic beads, and color pigments. In certain examples, the base coat layer can also include a dye. The polymeric resin can be a liquid resin that can include monomers that polymerize to form a polymer, and/or already polymerized polymers that can cure to form a solid polymer layer. Some examples of polymers that can be included in the polymeric resin include polyester, polyacrylic, and polyurethane.

In various examples, the thickness of the base coat layer can be from about 10 μm to about 20 μm. In other examples, the thickness can be from about 10 μm to about 15 μm or from about 15 μm to about 20 μm.

After applying the filler and polymeric resin mixture, the layer can be cured. In some examples, the layer can be cured by heating to a temperature from about 60° C. to about 160° C. In other examples, the curing temperature can be from about 60° C. to about 80° C., or from about 80° C. to about 120° C., or from about 120° C. to about 160° C. The layer can be heated at the curing temperature for a curing time. In some examples, the curing time can be from about 15 minutes to about 40 minutes, or from about 15 minutes to about 30 minutes, or from about 30 minutes to about 40 minutes.

### Physical Vapor Deposition Layers

The physical vapor deposition layer can include an alloy of gold and platinum. In some examples, the alloy can include from about 5 wt % to about 15 wt % gold and about 85 wt % to about 95 wt % platinum. In other examples, the alloy can include from about 5 wt % to about 10 wt % gold and from about 90 wt % to about 95 wt % platinum or from about 10 wt % to about 15 wt % gold and from about 85 wt % to about 90 wt % platinum.

As explained above, the physical vapor deposition layer can be formed by sputtering. A target made of an alloy of gold and platinum can be used in the sputtering process. Argon can be flowed as a sputtering gas during this process. Atoms of gold and platinum from the sputtering target can be deposited onto the substrate.

In certain examples, sputtering can be performed at a temperature from about 100° C. to about 180° C. In further examples, the temperature can be from about 100° C. to about 125° C. or from about 125° C. to about 150° C. or from about 150° C. to about 180° C. The pressure during sputtering can be controlled at about 10⁻⁶ torr to about 10⁻⁴ torr. In further examples, the pressure can be from about 10⁻⁶ torr to about 10⁻⁵ torr or from about 10⁻⁶ torr to about 10⁻⁴ torr. The thickness of the physical deposition layer can be from about 30 nm to about 5 μm, or from about 30 nm to about 1 μm, or from about 30 nm to about 500 nm, or from about 30 nm to about 200 nm. In some examples, sputtering can be performed for a time from about 10 minutes to about 30 minutes, or from about 10 minutes to about 20 minutes, or from about 20 minutes to about 30 minutes.

### Anti-Fingerprint Layers

An anti-fingerprint layer can be applied over the physical vapor deposition layer. The anti-fingerprint layer can include an ultraviolet radiation-cured polymer mixed with an anti-fingerprint material. Anti-fingerprint materials can include materials such as silanes, fluorinated polymers, and hydrophobic polymers. A specific example silane is hexadecyl trimethoxy silane. In specific examples, the anti-fingerprint material can include a fluorinated polyolefin, a fluoroacrylate, a fluorosilicone acrylate, a fluorourethane, a perflouropolyether, a perfluoropolyoxetane, a fluorotelomer, polytetrafluoroethylene, polyvinylidenefluoride, a fluorosiloxane, a fluorinated ultraviolet radiation-curable polymer, or a combination thereof. In certain examples, fluorotelomers can be C-6 or lower in size. In other examples, the anti-fingerprint material can be a hydrophobic polymer that is C-7 or greater in size. In further examples, the ultraviolet radiation-curable polymer in the anti-fingerprint layer can include a polyacrylic, a polyurethane, a urethane acrylate, an acrylic acrylate, an epoxy acrylate, or a combination thereof. In some examples, the mixture can include the anti-fingerprint material in an amount of about 5 wt % to about 25 wt % and the remainder can be the ultraviolet radiation-curable resin. In further examples, the amount of the anti-fingerprint material can be from about 5 wt % to about 15 wt % or from about 15 wt % to about 25 wt %.

The mixture of the ultraviolet radiation-curable resin and the anti-fingerprint material can be applied to the surface of the coated substrate by a variety of application processes, such as spin coating, dipping, spraying, spreading, and so on. The composition can then be cured by exposure to UV radiation. In certain examples, the composition can be baked at a temperature from about 50° C. to about 60° C. for a period of time from about 10 minutes to about 15 minutes before exposure to UV radiation. After baking, the layer can be exposed to UV radiation at an intensity from about 700 mJ/cm² to about 1,200 mJ/cm². In other examples the UV radiation intensity can be from about 800 mJ/cm² to about 1,100 mJ/cm². The irradiation time can be from about 10 seconds to about 30 seconds in some examples. In other examples, the irradiation time can be from about 10 seconds to about 20 seconds, or from about 20 seconds to about 30 seconds.

### Definitions

It is noted that, as used in this specification and the appended claims, the singular forms “a,” “an,” and “the” include plural referents unless the content clearly dictates otherwise.

As used herein, the term “about” is used to provide flexibility to a numerical range endpoint by providing that a given value may be “a little above” or “a little below” the endpoint. The degree of flexibility of this term can be dictated by the particular variable based on experience and the associated description herein.

As used herein, a plurality of items, structural elements, compositional elements, and/or materials may be presented in a common list for convenience. However, these lists should be construed as though individual members of the list are individually identified as a separate and unique member. Thus, no individual member of such list should be construed as a de facto equivalent of any other member of the same list solely based on their presentation in a common group without indications to the contrary.

Concentrations, dimensions, amounts, and other numerical data may be presented herein in a range format. It is to be understood that such range format is used merely for convenience and brevity and should be interpreted flexibly to include the numerical values explicitly recited as the limits of the range, but also all the individual numerical values or sub-ranges encompassed within that range as if individual numerical values and sub-ranges are explicitly recited. For example, an atomic ratio range of about 1 at % to about 20 at % should be interpreted to include the explicitly recited limits of about 1 at % and about 20 at %, but also to include individual atomic percentages such as 2 at %, 11 at %, 14 at %, and sub-ranges such as 10 at % to 20 at %, 5 at % to 15 at %, etc.

The terms, descriptions, and figures used herein are set forth by way of illustration and are not meant as limitations. Many variations are possible within the disclosure, which is intended to be defined by the following claims—and equivalents—in which all terms are meant in the broadest reasonable sense unless otherwise indicated.

### EXAMPLES

The following illustrates examples of the present disclosure. However, it is to be understood that the following are merely illustrative of the application of the principles of the present disclosure. Numerous modifications and alternative devices, methods, and systems may be devised without departing from the spirit and scope of the present disclosure. The appended claims are intended to cover such modifications and arrangements.

### Example 1—Coated Metal Substrate

An example coated substrate for an electronic device is made using the following process. A substrate is made from an aluminum sheet having a thickness of about 2 mm. The substrate is treated with micro-arc oxidation to form a micro-arc oxidation layer that is 5 μm thick. A primer layer is then added by coating one side of the substrate with a primer composition including a polyurethane polymer. The primer layer is cured by heating at 80° C. for 15 minutes. A base coat layer is then added by coating a base coat composition over the primer layer. The base coat composition includes a colored pigment in a thermally curable polyacrylic resin. The base coat is cured by heating at 80° C. for 40 minutes.

A physical vapor deposition layer is added after the base coat. The physical vapor deposition layer is formed by sputtering a target made of an alloy of 10 wt % gold and 90 wt % platinum. The sputtering process is performed at a temperature of 150° C., at a pressure of 10⁻⁴ torr, with argon flowing as a sputtering gas. The sputtering is continued for 30 minutes to form a PVD layer that is about 1 μm thick.

An anti-fingerprint layer is applied over the physical vapor deposition layer. The anti-fingerprint layer is formed by applying a composition including 75 wt % of a UV-curable polyacrylic resin and 25 wt % of hexadecyl trimethoxy silane as an anti-fingerprint material. The anti-fingerprint composition is applied at a thickness of 100 nm. The layer is then baked at 50° C. for 15 minutes and cured by exposure to UV radiation at an intensity of 1,000 mJ/cm² for 30 seconds.

The resulting coated aluminum substrate has a coefficient of friction of about 0.2 when measured by rubbing against an aluminum ball, and a specific wear rate of about 10⁻⁸ mm³/Nm when measured by rubbing against an aluminum ball.

### Example 2—Coated Plastic Substrate

Another example coated substrate for an electronic device is made using the following process. A substrate is made from plastic having a thickness of about 2 mm. A primer layer is added by coating one side of the substrate with a primer composition including an epoxy polymer. The primer layer is cured by heating at 80° C. for 15 minutes. A base coat layer is then added by coating a base coat composition over the primer layer. The base coat composition includes a metal powder in a thermally curable polyacrylic resin. The base coat is cured by heating at 80° C. for 40 minutes.

A physical vapor deposition layer is added after the base coat. The physical vapor deposition layer is formed by sputtering a target made of an alloy of 15 wt % gold and 85 wt % platinum. The sputtering process is performed at a temperature of 120° C., at a pressure of 10⁻⁴ torr, with argon flowing as a sputtering gas. The sputtering is continued for 10 minutes to form a PVD layer that is about 100 nm thick.

An anti-fingerprint layer is applied over the physical vapor deposition layer. The anti-fingerprint layer is formed by applying a composition including 85 wt % of a UV-curable polyacrylic resin and 15 wt % of hexadecyl trimethoxy silane as an anti-fingerprint material. The anti-fingerprint composition is applied at a thickness of 100 nm. The layer is then baked at 50° C. for 15 minutes and cured by exposure to UV radiation at an intensity of 1,000 mJ/cm² for 30 seconds.

The resulting coated aluminum substrate has a coefficient of friction of about 0.3 when measured by rubbing against an aluminum ball, and a specific wear rate of about 10⁻⁸ mm³/Nm when measured by rubbing against an aluminum ball. In some examples, specific wear rate can be measured using a standard method according to ASTM G-99 standards.

What is claimed is:

1. A coated substrate for an electronic device comprising:
a substrate;
a physical vapor deposition layer over the substrate, wherein the physical vapor deposition layer comprises an alloy of gold and platinum; and
an anti-fingerprint layer over the physical vapor deposition layer, wherein the anti-fingerprint layer comprises an ultraviolet radiation-cured polymer mixed with an anti-fingerprint material, wherein the anti-fingerprint material comprises a silane, a fluorinated polymer, a hydrophobic polymer, or a combination thereof.

2. The coated substrate of claim 1, wherein the substrate comprises plastic, carbon fiber, or a light metal.

3. The coated substrate of claim 1, wherein the substrate comprises aluminum, magnesium, lithium, titanium, or an alloy thereof, and wherein the substrate further comprises a micro-arc oxidation layer or a passivation layer on a surface of the substrate.

4. The coated substrate of claim 1, wherein the physical vapor deposition layer includes from about 5 wt % to about 15 wt % gold and from about 85 wt % to about 95 wt % platinum.

5. The coated substrate of claim 1, wherein the physical vapor deposition layer has a thickness from about 30 nm to about 5 μm and wherein the anti-fingerprint layer has a thickness from about 10 nm to about 100 nm.

6. The coated substrate of claim 1, wherein the ultraviolet radiation-cured polymer of the anti-fingerprint layer comprises a polyacrylic, a polyurethane, a urethane acrylate, an acrylic acrylate, an epoxy acrylate, or a combination thereof, and wherein the anti-fingerprint material comprises a fluorinated polyolefin, a fluoroacrylate, a fluorosilicone acrylate, a fluorourethane, a perflouropolyether, a perfluoropolyoxetane, a fluorotelomer, polytetrafluoroethylene, polyvinylidenefluoride, a fluorosiloxane, a fluorinated ultraviolet radiation-curable polymer, or a combination thereof.

7. The coated substrate of claim 1, wherein the coated substrate has a coefficient of friction from about 0.2 to about 0.3 when measured by rubbing against an aluminum ball, and a specific wear rate from about 10⁻⁹ mm³/Nm to about 10⁻⁸ mm³/Nm when measured by rubbing against an aluminum ball.

8. The coated substrate of claim 1, further comprising a primer layer over the substrate and under the physical vapor deposition layer, wherein the primer layer comprises a polymer.

9. The coated substrate of claim 8, further comprising a base coat layer over the primer layer, wherein the base coat layer comprises a filler dispersed in a polymeric resin.

10. A method of making a coated substrate for an electronic device comprising:
depositing a physical vapor deposition layer over a substrate, wherein the physical vapor deposition layer comprises an alloy of gold and platinum; and
depositing an anti-fingerprint layer over the physical vapor deposition layer, wherein the anti-fingerprint layer comprises an ultraviolet radiation-cured polymer mixed with an anti-fingerprint material, wherein the anti-fingerprint material comprises a silane, a fluorinated polymer, a hydrophobic polymer, or a combination thereof.

11. The method of claim 10, wherein the substrate comprises aluminum, magnesium, lithium, titanium, or an alloy thereof, and wherein the method further comprises forming a micro-arc oxidation layer or a passivation layer on a surface of the substrate.

12. The method of claim 10, wherein the physical vapor deposition layer is deposited by sputtering a gold and platinum alloy target comprising from about 5 wt % to about 15 wt % gold and from about 85 wt % to about 95 wt % platinum.

13. An electronic device comprising a housing carrying electronic components of the electronic device, wherein the housing includes a coated substrate comprising:
a substrate;
a physical vapor deposition layer over the substrate, wherein the physical vapor deposition layer comprises an alloy of gold and platinum; and
an anti-fingerprint layer over the physical vapor deposition layer, wherein the anti-fingerprint layer comprises an ultraviolet radiation-cured polymer mixed with an anti-fingerprint material, wherein the anti-fingerprint material comprises a silane, a fluorinated polymer, a hydrophobic polymer, or a combination thereof.

14. The electronic device of claim 13, wherein the physical vapor deposition layer includes from about 5 wt % to about 15 wt % gold and from about 85 wt % to about 95 wt % platinum, wherein the ultraviolet radiation-cured polymer of the anti-fingerprint layer comprises a polyacrylic, a polyurethane, a urethane acrylate, an acrylic acrylate, an epoxy acrylate, or a combination thereof, and wherein the anti-fingerprint material comprises a fluorinated polyolefin, a fluoroacrylate, a fluorosilicone acrylate, a fluorourethane, a perflouropolyether, a perfluoropolyoxetane, a fluorotelomer, polytetrafluoroethylene, polyvinylidenefluoride, a fluorosiloxane, a fluorinated ultraviolet radiation-curable polymer, or a combination thereof.

15. The electronic device of claim 13, wherein the electronic device comprises a display, a personal computer, a laptop computer, a tablet, a media player, a smart device, a keyboard, or a combination thereof.
